(19) United States
(12) Patent Application Publication
(10) Pub. No.: US 2003/0140857 A1
(43) Pub. Date: Jul. 31, 2003

(54) Apparatus and method for low pressure CVD deposition of tungsten and tungsten nitride

(75) Inventors: Salvador P. Umotoy, Antioch, CA (US); Lawrence Chung-Lai Lei, Milpitas, CA (US); Ling Chen, Sunnyvale, CA (US); Anzhong Chang, San Jose, CA (US); Seshadri Ganguli, Sunnyvale, CA (US)

Correspondence Address: APPLIED MATERIALS, INC., 2881 SCOTT BLVD. M/S 2061, SANTA CLARA, CA, 95050, US

(73) Assignee: Applied Materials, Inc., Santa Clara, CA (US)

(21) Appl. No.: 10/058,670

(22) Filed: Jan. 28, 2002

(51) Int. Cl. C23C 16/00

(52) U.S. Cl. 118/726; 427/255.28; 118/715

(57) ABSTRACT

In accordance with an embodiment of the invention, a processing chamber is configured to carry out chemical vapor deposition (CVD). An ampoule vaporizer is fastened to the chamber, and is configured to convert a fluorine-free tungsten-containing solid compound to vapor delivered to the chamber for use in the CVD. In one embodiment, the solid compound is tungsten hexacarbonyl (W(CO)6). In another embodiment, a mass flow controller is fastened to the chamber, and is configured to receive the vapor from the ampoule vaporizer, regulate the flow of the vapor, and deliver the vapor to the chamber. In yet another embodiment, the chamber includes a funnel-shaped dispersion plate configured to receive a gas mixture and direct the gas mixture toward a surface of the wafer in a substantially uniform manner.

### BACKGROUND OF THE INVENTION

Deposition of tungsten over a semiconductor substrate is a common step in the formation of some integrated circuit (IC) structures. For example, tungsten is commonly used to provide electrical contact to portions of a semiconductor substrate and between adjacent metal layers. More recently, with the widespread use of copper interconnects in ICs, a layer of tungsten is used over and/or under the copper interconnects to prevent atoms of copper from adversely interacting with and creating leakage paths through the various dielectric layers used in the IC.

It has been known to use tungsten fluoride (WF₆) vapor as a process gas for formation of tungsten films by chemical vapor deposition (CVD). However, since fluorine tends to attack copper or form an undesired compound due to its high diffusivity, some semiconductor manufacturers prefer to use other sources of tungsten, such as tungsten hexacarbonyl (W(CO)₆) vapor. Tungsten hexacarbonyl, although a solid at room temperature and atmospheric pressure, may be vaporized under suitable conditions of pressure and temperature to obtain a gaseous phase of the compound which can then be used in CVD processing to form a film or layer of metallic tungsten on a semiconductor wafer.

It is desirable that a layer of metal, such as tungsten, being deposited by CVD on a semiconductor wafer be uniform in thickness. To achieve this, a chemical vapor compound of the material flowing into a reaction chamber where the semiconductor wafer is being processed should be controlled in flow direction and amplitude so that the vapor is evenly distributed and flows uniformly toward the wafer. This is especially true of materials such as tungsten hexacarbonyl vapor, the molecules of which have relatively high weight and inertia.

Commonly, an ampoule vaporizer is used to convert a solid compound to vapor. The solid compound is placed in the ampoule vaporizer and then heated to a high enough temperature and under suitable pressure conditions to obtain a gaseous phase of the compound. A mass flow controller (MFC) may be used to regulate the flow of the vapor from the ampoule vaporizer to the reaction chamber. The ampoule vaporizer and the mass flow controller units are normally placed in the vicinity of the chamber, and the vapor is delivered to the chamber through pipe-lines.

This approach however suffers from a number of drawbacks when a compound such as W(CO)₆ is used as the precursor gas in a tungsten CVD process. W(CO)₆ in its solid form is converted to vapor at 70° C. and 1.5 Torr. However, because of the distance between the ampoule vaporizer and the chamber and the resulting drop in pressure from the ampoule vaporizer to the chamber, the pressure in the ampoule vaporizer needs to be increased to compensate for the pressure drop. If the pressure drop is not properly compensated for, the pressure near the surface of the wafer in the chamber will be lower than necessary resulting in a slower deposition rate and requiring a stronger exhaust pump to properly exhaust the unwanted gases in the chamber. The required higher pressure in the vaporizer in turn necessitates use of a higher temperature in order to convert W(CO)₆ to gas phase and maintain the gas phase. Further, in delivering the W(CO)₆ vapor from the ampoule vaporizer to the chamber, the high temperature needs to be maintained in the delivery devices (e.g., the pipe-lines) through which the W(CO)₆ vapor travels to prevent the W(CO)₆ vapor from turning back into solid. This requires heating the delivery device and maintaining the high temperature which complicates the integration of the different equipment units and can pose safety hazards. Also, higher temperature levels (e.g., above 100° C.) can result in partial decomposition of the precursor gas, leading to deposition of a high resistivity film.

In view of the above, improved methods and apparatus for delivering W(CO)₆ and other vapors to substrate processing chambers are desirable.

### BRIEF SUMMARY OF THE INVENTION

In accordance with an embodiment of the invention, a processing chamber is configured to carry out chemical vapor deposition (CVD). An ampoule vaporizer is fastened to the chamber, and is configured to convert a fluorine-free tungsten-containing solid compound to vapor delivered to the chamber for use in the CVD. In one embodiment, the solid compound is tungsten hexacarbonyl (W(CO)6).

In another embodiment, a mass flow controller is fastened to the chamber, and is configured to receive the vapor from the ampoule vaporizer, regulate the flow of the vapor, and deliver the vapor to the chamber. In yet another embodiment, the ampoule vaporizer and the mass flow controller are fastened to a top lid of the chamber.

In another embodiment, a mixing fixture is configured to receive the vapor from the mass flow controller, mix the vapor with one or more other gas(es) and deliver the gas mixture to the chamber.

In another embodiment, the chamber includes a platform configured to receive a wafer, and a funnel-shaped dispersion plate configured to receive the gas mixture from the mixing fixture and direct the gas mixture toward a surface of the wafer in a substantially uniform manner.

In yet another embodiment, the dispersion plate includes a body having a center axis, an input face, an output face, and a thickness between the faces, and an input opening along the center axis in the input face for receiving a stream of vapor. The input opening extends radially from the center axis to on output opening in the output face through which the stream of vapor exits.

In another embodiment, the input opening extends along the center axis to form a hole before extending radially to the output opening, the hole having a substantially hour-glass shape. In yet anther embodiment, the hole extends radially from the center axis to the output opening forming an angle having a value at the output opening in the range of 60-85 degrees.

In another embodiment, the chamber further includes a face plate between the dispersion plate and the wafer. The face plate has a plurality of passages extending from a top surface to a bottom surface of the plate, and is configured to present a suitably uniform thermal profile to the wafer so that the wafer may be uniformly heated.

Other advantages and features of the present invention will be apparent from the accompanying drawings and the description thereof.

### BRIEF DESCRIPTION OF THE DRAWINGS

FIG. 1 shows an integrated CVD chamber, ampoule vaporizer, and mass flow controller configuration in accordance with an embodiment of the invention;

FIG. 2 shows a vertical sectional view of a chamber with ampoule vaporizer mounted on top of the chamber in accordance with an embodiment of the invention;

FIG. 3 shows a lid portion of a processing chamber, an ampoule vaporizer, mass flow controller, and the associated pipe-line for vapor delivery, in accordance with an embodiment of the invention;

FIG. 4 shows a vertical sectional view of a funnel-shaped dispersion plate in accordance with the invention; and

FIG. 5 shows a graph illustrating the relationship of vapor phase to solid phase of a material such as tungsten hexacarbonyl as a function of temperature versus pressure.

### DETAILED DESCRIPTION OF THE INVENTION

In accordance with an embodiment of the present invention, an ampoule vaporizer and a mass flow controller are efficiently integrated with a processing chamber to facilitate converting solid compounds, such as W(CO)₆, into vapor and delivering the vapor to the chamber under low pressure and low temperature conditions. Further, a funnel-shaped dispersion plate is used in the processing chamber to ensure that such difficult to handle vapors as the W(CO)₆ vapor is evenly distributed over the substrate under low pressure conditions.

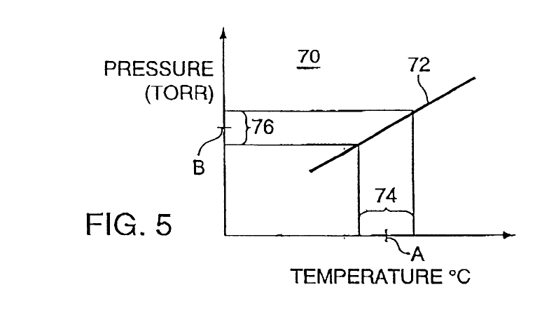

Referring to FIG. 5, there is shown a graph 70 illustrating the relationship of vapor phase to solid phase of a material such as tungsten hexacarbonyl as a function of temperature versus pressure. The horizontal axis of graph 70 indicates temperature in degrees centigrade (° C.), and the vertical axis indicates pressure in Torr. The axes are not necessarily linear. Graph 70 shows a line 72 along which the material is in vapor phase. When the temperature or pressure moves sufficiently to the left or up in graph 70 away from line 72, the material returns to solid (or liquid) state. For a given material (e.g., tungsten hexacarbonyl), when being used in CVD processing there are conveniently employed a range of temperatures, indicated in graph 70 by a bracket 74, and a range of pressures indicated by a bracket 76 with a nominal operating value of temperature at a point A and of pressure at a point B. In the case of tungsten hexacarbonyl, the temperature range 74 may be 60° C. to 110° C. with a nominal operation value at point A of about 70° C. The pressure range 76 may be a few milli-Torr to 1.5 Torr with an operation value at point B of about 150 milli-Torr.

It is apparent from graph 70, that a material such as W(CO)₆, when employed in CVD processing requires a low chamber pressure (e.g., about 150 milli-Torr). As indicated earlier, such material at normal atmospheric temperature and pressure is a solid but it can be made to sublime into vapor. It is therefore important to prevent the vapor from returning to solid (or liquid) phase in passing from the ampoule vaporizer to the processing chamber, and from being significantly impeded in its flow.

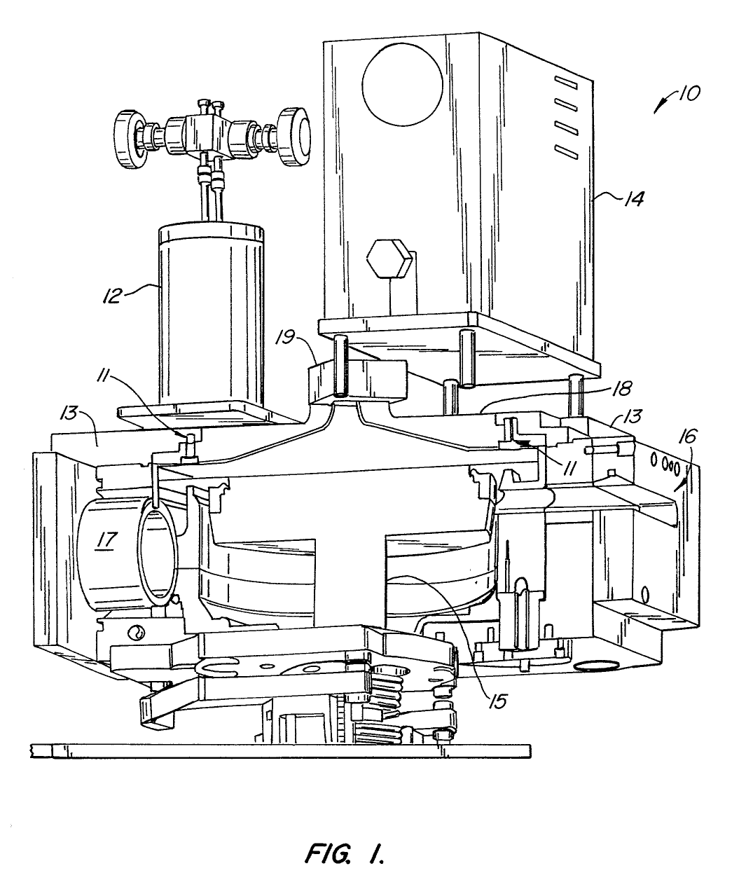

FIG. 1 shows an integrated CVD chamber, ampoule vaporizer, and mass flow controller configuration 10 in accordance with an embodiment of the invention. An ampoule vaporizer 12 and a mass flow controller 14 are mounted directly on top of the lid of a processing chamber 16. A vertical sectional view of chamber 16 is shown in FIG. 1 in order to reveal the interior of chamber 16. As shown, chamber 16 includes a susceptor or platform 15 on which a wafer (not shown) is placed for CVD processing, a mixing fixture 19 for mixing one or more process gases with one or more carrier gases or other types of gas, and a dispersion plate 18 embodying features of the invention for controlling and directing the flow of vaporized material into chamber 16 so that it flows uniformly down toward the wafer. Chamber 16 is hermetically sealable and can be maintained at near-vacuum pressures. Platform 15 is heated (by means not shown) and in turn heats the wafer to an elevated temperature. At such elevated temperature vaporized material flowing into the chamber upon reaching and touching the surface of the wafer will break down into its constituents and a tungsten film is deposited onto a top surface of the wafer. Unwanted residues and gas are exhausted from the chamber via an exhaust port 17.

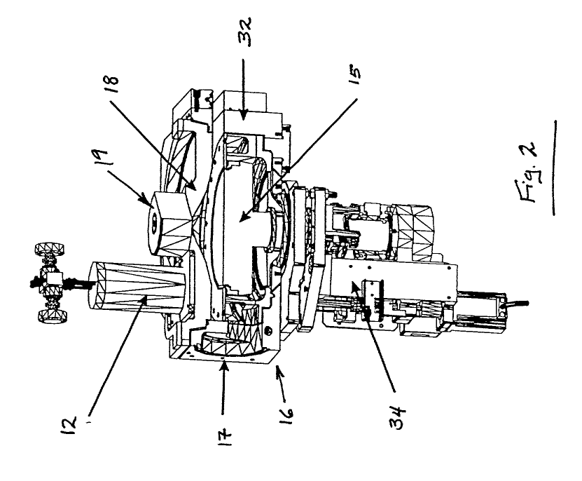

FIG. 2 shows another vertical sectional view of chamber 16 with ampoule vaporizer 12 mounted on top of chamber 16. MFC 14 and the pipeline for delivering the vapor from ampoule vaporizer 12 to chamber 16 are not shown in this figure. In this figure, in addition to the chamber components identified in FIG. 1, the chamber body which encloses chamber 16 is identified by reference numeral 32, and the lift mechanism for moving platform 15 up or down is identified by reference numeral 34. Chamber body 32, exhaust port 17, platform 15, lift mechanism 34, as well other chamber components not identified herein may be provided in accordance with conventional practices. For example, these chamber components may be the same as in a known CVD chamber such as the TixZ chamber available from Applied Materials, Inc., the assignee of this application, and used for TiCl₄ deposition processing.

In FIGS. 1 and 2, the pipe-line for delivering the vapor produced in ampoule vaporizer 12 to chamber 16 is not shown in order to more clearly show the integration of ampoule vaporizer 12 and MFC 14 with chamber 16. The vapor produced in ampoule vaporizer 12 is first delivered to MFC 14, and then from MFC 14 to mixing fixture 19 wherein the vapor is mixed with other gas(es). Mixing fixture 19 then supplies the gas mixture to dispersion plate 18 which in turn directs the gas mixture uniformly over the surface of the wafer on platform 15. Commercially available ampoule vaporizers (such as Schumacher Model number BK500SSN) and mass flow controllers (such as MKS model number 1153 or 1150) may be used.

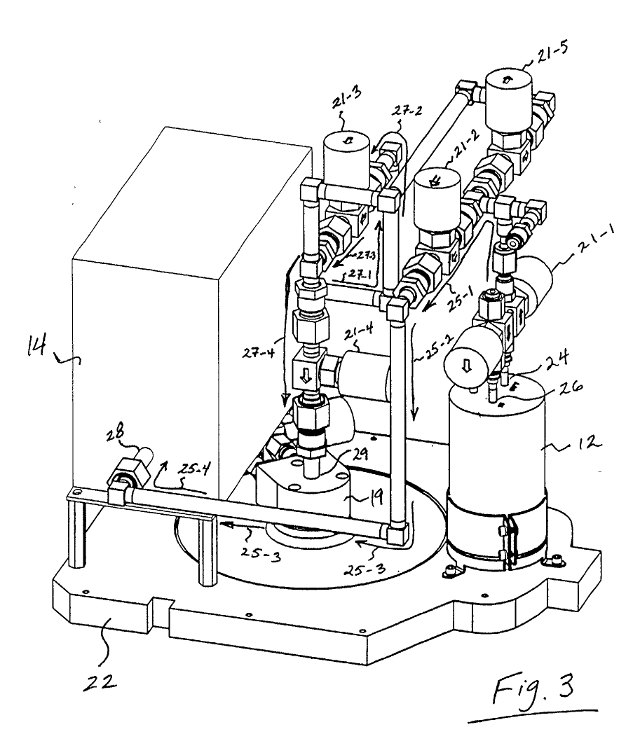

Mixing fixture 19 (well known in the art) may, if deemed desirable, apply heat and ultrasonic energy to material flowing to it from MFC to ensure that the vaporized material is entirely vaporized and free of droplets or particles. An inlet 29 (FIG. 3) directs the vapor into mixing fixture 19. Other inlet(s) through which different gas(es) flow into mixing fixture 19 are not shown in the figure. Mixing Fixture 19 may be formed partially or completely of aluminum which provides excellent heat conduction leading to uniformity of temperature inside mixing fixture 19. Other materials that have suitable thermal conduction may be similarly used. The appropriate dimensions of mixing fixture 19 depend on many factors such as the process being performed, the precursor gas employed, the volume/dimension of processing chamber 16, operating temperature, pressure, flow rate, and carrying gas. Examples of mixing fixtures are disclosed in U.S. Pat. No. 6,302,965 B1, issued Oct. 16, 2001, entitled “Dispersion Plate for Flowing Vaporized [sec] Compounds used in Chemical Vapor Deposition of Films onto Semiconductor Surfaces”, and co-pending application Ser. No. 06/287,280, filed Apr. 28, 2001, entitled “Chemical Vapor Deposition Chamber”, both of which are commonly assigned with this application and are incorporated herein by reference in their entirety for any purpose.

FIG. 3 shows the lid portion 22 of chamber 16, ampoule vaporizer 12, MFC 14, and the pipe-line for vapor delivery from ampoule vaporizer 12 to chamber 16. The particular location of ampoule vaporizer 12 and MFC 14 on the lid as shown in FIGS. 1, 2, and 3 is intended to be illustrative and not limiting. The location of these units on the lid may vary depending on the particular shape of the chamber lid, the shape and design of ampoule vaporizer 12, MFC 14, mixing fixture 19, and the pipes connecting these units together. Vaporizer 12 and MFC 14 are fastened to the chamber lid such that the chamber lid can be opened and closed during chamber operation.

During normal operation, valves 21-1, 21-2, 21-3, and 21-4 are open while valve 21-5 is closed. Vapor (e.g., W(CO)₆ vapor) produced in ampoule vaporizer 12 flows out through ampoule vaporizer outlet 24, travels through the pipes along the path indicated by the set of arrows marked as 25-1 through 25-4, and enters MFC 14 through MFC inlet 28. MFC 14 then in turn delivers the vapor through an MFC outlet (not shown) located on the side of MFC 14 opposite the side where the MFC inlet 28 is located. The vapor then travels through another set of pipes along the path indicated by a set of arrows marked by reference numerals 27-1 through 27-4, and enters mixing fixture inlet 29. As shown, from ampoule vaporizer outlet 24 to MFC inlet 28, the vapor passes through valves 21-1 and 21-2, and from the MFC outlet to mixing fixture inlet 29, the vapor passed through valves 21-3 and 21-4. Valve 21-5 serves to provide a bypass route so that the vapor produced in ampoule vaporizer 12 can be piped directly to mixing fixture 29 without passing through MFC 14. Thus, to bypass MFC 14, valves 21-1, 21-4 and 21-5 are opened and valves 21-2 and 21-3 are closed, and the vapor thus travels through the pipes along the path indicated by arrows marked by reference numerals 31-1 through 31-3. The invention is not limited to this particular pipe-line and valve configuration, and other configurations can be implemented by one skilled in the art in view of the teachings of the present invention.

Thus, by integrating chamber 16, ampoule vaporizer 12, and MFC 14 as a single unit, the distance between the ampoule vaporizer/MFC and the surface of the wafer in the chamber is substantially reduced compared to other approaches. The reduced distance minimizes the pressure drop from ampoule vaporizer 12 to the wafer, allowing lower pressure to be used in the ampoule vaporizer to convert such solids as W(CO)₆ into vapor and to maintain the vapor phase. The lower pressure in turn allows use of lower temperature in ampoule vaporizer 12 for conversion of the solid compound to vapor. Also, the reduced distance improves the response time of the MFC and help achieve a more repeatable process performance. Further, the equipment integration complications and the safety concerns associated with high temperature pipe-lines delivering the vapor from an ampoule vaporizer located a distance away from the chamber to the chamber are eliminated.

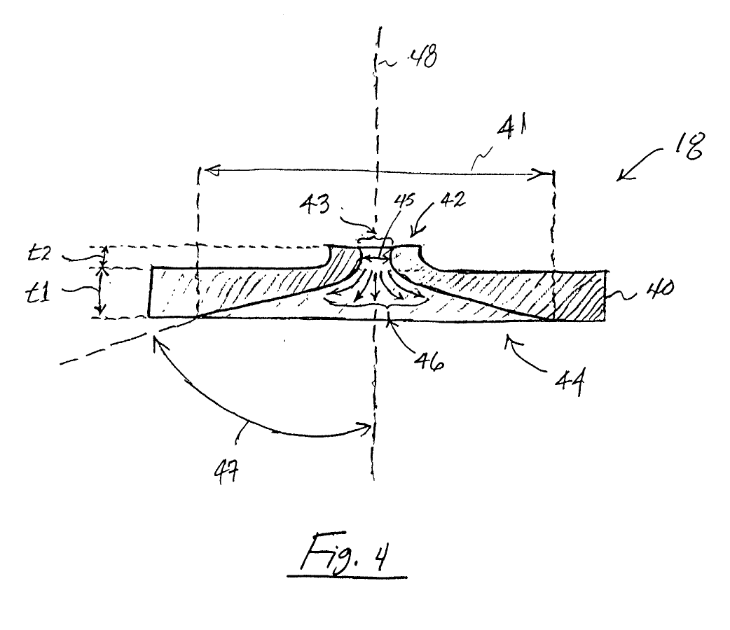

Conventionally, a shower-head is used to deliver gases to the wafer surface in the chamber. However, the pressure drop across the shower-head makes the uniform delivery of such heavy gases as W(CO)₆ under low pressure conditions difficult to achieve. In accordance with an embodiment of the invention, a funnel-shaped dispersion plate 18 (FIGS. 1 and 2) controls and directs the flow of a relatively heavy vapor, such as tungsten hexacarbonyl, under low pressure conditions so that the vapor flows from the dispersion plate in a substantially uniform manner with minimal pressure drop across the dispersion plate. A vertical sectional view of the funnel-shaped dispersion plate 18 is shown in FIG. 4. Dispersion plate 18 includes a body 40 having a center axis 48, an input face generally shown at 42, an output face generally shown at 44, and a thickness (made up of t1+t2) between the faces with an entrance 43 along center axis 48 for receiving a stream of vaporized material. As shown, the funnel-shaped opening extends radially from center axis 48. An angle between center axis 48 and the sloped inner surface of the plate is marked with reference numeral 47. The diameter of the opening at output face 44 is marked with reference numeral 41. An inner diameter of the opening at input face 42 is marked with reference numeral 45. Angle 47 is 0° at the inner diameter 45, and increases to its largest value at the output face 44.

Vaporized material from gas mixer 19 flowing into entrance 43 flows through plate 18 as shown by arrows 46. The particular shape and configuration of plate 18, in the specific embodiment of the invention shown herein, ensures that a relatively heavy vapor, such as W(CO)₆, will flow from the plate uniformly down toward the wafer. An important result of this is that a thin layer of material (e.g., tungsten metal less than a micron thick) can be deposited with improved uniformity (i.e., uniform thickness) across the surface of the wafer.

Dispersion plate 18 has high-flow-conductance, that is, low pressure drop across the plate, of the vapor flowing through it. This enables plate 18 to function well in CVD processing using materials such as W(CO)₆ where the pressure within the chamber must be maintained at a low value (e.g., 150 milli-Torr or lower). The low pressure drop across plate 18 is partially achieved by the relatively short entry hole (i.e., short t2) and the wide outlet area at the output face 44.

Dispersion plate 18 is advantageously made from a disk-like solid block of a metal such as aluminum having high heat conductivity and ease of machining. Plate 18 is attached to an upper wall 13 (FIG. 1) of chamber 16 by a plurality of bolts 11 (only two of which are shown) and together with wall 13 forms a top seal for chamber 16. Dimensions t1, 41, and 45 play an important in achieving the uniform delivery of the vapor. In the specific embodiment of the invention illustrated herein, diameter 41 at the outer face 44 is in the range of 7-9 inches; the inner diameter 45 is in the range of 0.6-1 inches; and the thicknesses t1 and t2 are in the range of 1.3-2.1 inches and 0.15-0.25 inches, respectively. Angle 47 at the output face 44 is in the range of 60-85°. In one embodiment, diameter 41 is 8 inches, the inner diameter 45 is 0.8 inches, the thickness t1 and t2 are 1.7 and 0.2 inches respectively, and angle 47 at the output face is 75°. Note that the values for the different dimensions and angles are selected primarily based on the gas type and flow rate, chamber pressure, and wafer size. For example, for a lower chamber pressure, angle 47 at the output face is increased, thickness t1 is decreased, and inner diameter 45 is increased. The above values and ranges correspond to a chamber adapted to receive 8 inch wafers, and may be varied by one skilled in the art in view of this disclosure to accommodate a chamber adapted to receive a different size wafer.

In one embodiment, a face plate (not shown in the figures) is interposed between dispersion plate 18 and the wafer to present a suitably uniform thermal profile to the wafer so that the wafer may be uniformly heated. The uniformity of the gas mixture and the uniform thermal environment for the wafer tend to promote highly uniform deposition of a thin film across the surface of the wafer. An example of such a face plate is disclosed in the previously cited patent application Ser. No. 06/287,280, filed Apr. 28, 2001, entitled “Chemical Vapor Deposition Chamber”.

In accordance with another embodiment of the invention, a dispersion plate with a plurality of passages for flow of vapor, disclosed in the previously cited U.S. Pat. No. 6,302,965 B1 (“the '965 patent”), issued Oct. 16, 2001, is used instead of plate 18. The particular design of the dispersion plate of the '965 patent results in a relatively low pressure drop to the vapor flowing through them and provides dispersion of vapor flowing through the plate such that vapor flows evenly onto the surface of the wafer. Other advantages and features of the dispersion plate of the '965 patent are cited in the '965 patent.

The above description is intended in illustration and not in limitation of the invention. Various changes or modifications in the integrated system 10 embodying features of the invention may occur to those skilled in the art and can be made without departing from the spirit or scope of the invention as set forth herein and as defined by the accompanying claims. For example, the invention is not limited to use with only tungsten hexacarbonyl but is useful with other materials. Further, the invention is not limited to a particular pipe-line arrangement directing the vapor between the ampoule vaporizer, the MFC, and the gas mixer. Still further, the dispersion plate is not limited to a particular set of dimensions or diameter of a dispersion late, or to the particular numbers, sizes and angles as described above. Also, the invention is not limited to a particular type of chamber. The lid-mounted vaporizer and MFC aspect of the invention may be applied to chamber designs and structures other than those disclosed herein.

Therefore, the scope of the present invention should be determined not with reference to the above description but should, instead, be determined with reference to the appended claims, along with their full scope of equivalents.

What is claimed is:

1. An apparatus comprising:
a processing chamber configured to carry out chemical vapor deposition (CVD), the chamber including a platform configured to receive a wafer;
an ampoule vaporizer fastened to the chamber, configured to convert a fluorine-free tungsten-containing solid compound to vapor; and
a funnel-shaped dispersion plate configured to receive a gas mixture including the vapor and direct the gas mixture toward a surface of the wafer in a substantially uniform manner.

2. The apparatus of claim 1 further comprising a mass flow controller fastened to the chamber, configured to receive the vapor from the ampoule vaporizer and regulate the flow of the vapor.

3. The apparatus of claim 2 further comprising a mixing fixture configured to receive the vapor from the mass flow controller, mix the vapor with one or more other gas(es) to form the gas mixture, and deliver the gas mixture to the dispersion plate.

4. The apparatus of claim 1 wherein the solid compound is tungsten hexacarbonyl (W(CO)₆).

5. The apparatus of claim 2 wherein the ampoule vaporizer and the mass flow controller are fastened to a top lid of the chamber.

6. The apparatus of claim 1 wherein the chamber further includes a face plate between the dispersion plate and the wafer, the face plate having a plurality of passages extending from a top surface to a bottom surface of the plate, and being configured to present a suitably uniform thermal profile to the wafer so that the wafer may be uniformly heated.

7. The apparatus of claim 1 wherein the dispersion plate comprises:
a body having a center axis, an input face, an output face, and a thickness between the faces; and
an input opening along the center axis in the input face for receiving a stream of vapor, the input opening extending radially from the center axis to on output opening in the output face through which the stream of vapor exits.

8. The apparatus of claim 7 wherein the input opening extends along the center axis to form a hole before extending radially to the output opening, the hole having a substantially hour-glass shape.

9. The apparatus of claim 8 wherein the hole extends radially from the center axis to the output opening forming an angle having a value at the output opening in the range of 60-85 degrees.

10. An apparatus comprising:
a processing chamber configured to carry out chemical vapor deposition (CVD); and
an ampoule vaporizer fastened to the chamber, configured to convert a fluorine-free tungsten-containing solid compound to vapor delivered to the chamber for use in the CVD.

11. The apparatus of claim 10 further comprising:
a mass flow controller fastened to the chamber, configured to receive the vapor from the ampoule vaporizer and regulate the flow of the vapor.

12. The apparatus of claim 10 wherein the solid compound is tungsten hexacarbonyl (W(CO)₆).

13. The apparatus of claim 11 wherein the ampoule vaporizer and the mass flow controller are fastened to a top lid of the chamber.

14. The apparatus of claim 11 further comprising a mixing fixture configured to receive the vapor from the mass flow controller, mix the vapor with one or more other gas(es), and deliver the resulting gas mixture to the chamber interior.

15. The apparatus of claim 14 wherein the chamber comprises:
a platform configured to receive a wafer; and
a funnel-shaped dispersion plate configured to receive the gas mixture from the mixing fixture and direct the gas mixture toward a surface of the wafer in a substantially uniform manner.

16. The apparatus of claim 15 wherein the dispersion plate comprises:
a body having a center axis, an input face, an output face, and a thickness between the faces;
an input opening along the center axis in the input face for receiving a stream of vapor, the input opening extending radially from the center axis to on output opening in the output face through which the stream of vapor exits.

17. The apparatus of claim 16 wherein the input opening extends along the center axis to form a hole before extending radially to the output opening, the hole having a substantially hour-glass shape.

18. The apparatus of claim 17 wherein the hole extends radially from the center axis to the output opening forming an angle having a value at the output opening in the range of 60-85 degrees.

19. The apparatus of claim 15 wherein the chamber further includes a face plate between the dispersion plate and the wafer, the face plate having a plurality of passages extending from a top surface to a bottom surface of the plate, and being configured to present a suitably uniform thermal profile to the wafer so that the wafer may be uniformly heated.

20. A chemical vapor deposition method for forming a layer of tungsten on a wafer, the method comprising:
placing a wafer in a processing chamber;
converting a fluorine-free tungsten-containing solid compound to vapor using an ampoule vaporizer fastened to the chamber;
delivering the vapor to a mixing fixture configured to mix the vapor with one or more other gas(es); and
introducing the gas mixture into the processing chamber for forming the layer of tungsten.

21. The method of claim 20 wherein the solid compound is tungsten hexacarbonyl (W(CO)₆).

22. The method of claim 20 further comprising:
delivering the vapor from the ampoule vaporizer to the mixing fixture through a mass flow controller fastened to the chamber, the mass flow controller regulating the flow of the vapor.

23. The method of claim 22 wherein the ampoule vaporizer and the mass flow controller are fastened to a top lid of the chamber.

24. The method of claim 22 further comprising:
directing the gas mixture provided by the mixing fixture toward a surface of the wafer in a uniform manner using a funnel-shaped dispersion plate.

25. The method of claim 24 wherein the dispersion plate includes a body having a center axis, an input face, an output face, a thickness between the faces, and an input opening along the center axis in the input face for receiving a stream of vapor, the input opening extending radially from the center axis to on output opening in the output face through which the stream of vapor exits.

26. The method of claim 25 wherein the input opening extends along the center axis to form a hole before extending radially to the output opening, the hole having a substantially hour-glass shape.

27. The method of claim 26 wherein the hole extends radially from the center axis to the output opening forming an angle having a value at the output opening in the range of 70-85 degrees.

28. The method of claim 24 further comprising:
directing the gas mixture through a face plate positioned between the dispersion plate and the wafer, the face plate having a plurality of passages extending from a top surface to a bottom surface of the plate, and being configured to present a suitably uniform thermal profile to the wafer so that the wafer may be uniformly heated.

29. A processing chamber configured to carry out chemical vapor deposition (CVD), comprising:
a platform configured to receive a wafer; and
a funnel-shaped dispersion plate configured to receive a gas mixture and direct the gas mixture toward a surface of the wafer in a substantially uniform manner.

30. The chamber of claim 29 further comprising a mixing fixture configured to receive a fluorine-free tungsten-containing precursor and one or more carrier gas(es) to form the gas mixture, and deliver the gas mixture to the dispersion plate.

31. The chamber of claim 29 wherein the fluorine-free tungsten-containing precursor is tungsten hexacarbonyl (W(CO)₆) vapor.

32. The chamber of claim 29 wherein the dispersion plate comprises:
a body having a center axis, an input face, an output face, and a thickness between the faces;
an input opening along the center axis in the input face for receiving the gas mixture, the input opening extending radially from the center axis to on output opening in the output face through which the gas mixture exits.

33. The chamber of claim 32 wherein the input opening extends along the center axis to form a hole before extending radially to the output opening, the hole having a substantially hour-glass shape.

34. The chamber of claim 33 wherein the hole extends radially from the center axis to the output opening forming an angle having a value at the output opening in the range of 60-85 degrees.

35. The chamber of claim 30 further comprising a face plate between the dispersion plate and the wafer, the face plate having a plurality of passages extending from a top surface to a bottom surface of the plate, and being configured to present a suitably uniform thermal profile to the wafer so that the wafer may be uniformly heated.
